(19) United States
(12) Patent Application Publication
(10) Pub. No.: US 2013/0134308 A1
(43) Pub. Date: May 30, 2013

(54) SAMPLE OBSERVATION APPARATUS AND METHOD OF MARKING

(71) Applicant: HITACHI HIGH-TECHNOLOGIES CORPORATION, Tokyo (JP)

(72) Inventors: Fumiaki ENDO, Hitachinaka (JP); Kaori YAESHIMA, Hitachinaka-shi (JP)

(73) Assignee: HITACHI HIGH-TECHNOLOGIES CORPORATION, Tokyo (JP)

(21) Appl. No.: 13/687,922

(22) Filed: Nov. 28, 2012

(30) Foreign Application Priority Data
Nov. 28, 2011 (JP) 2011-259027

(51) Int. Cl. G01N 21/95; H01J 37/28

(52) U.S. Cl. CPC G01N 21/9501; H01J 37/28
USPC 250/307; 250/310

(57) ABSTRACT

If an indentation mark is put in the vicinity of a defect under constant conditions regardless of the film type of samples, surroundings of the mark become cracked or the mark may be too small to view, thus causing the problem of difficulty in viewing the mark or the defect. Another problem is that in a patterned wafer, an indentation mark is coincidentally put on a film not suited for marking. To solve such problems, an elemental analysis is conducted of a position to be marked and, on the basis of the analysis results, such indentation marking conditions as the pressing load, descending rate, and marking depth of an indenter are varied to perform marking suited for a film type. If the film type of the location to be marked cannot be concluded to be a registered film type, marking under wrong conditions is prevented by switching to manual setting. It is also possible to avoid putting marks on a material if the material is not suited for marking.

### BACKGROUND OF THE INVENTION

1. Field of the Invention

The present invention relates to a defect review apparatus using a scanning electron microscope to observe a sample by emitting an electron beam to the sample, and to a marking method in the defect review apparatus.

2. Background Art

Along with the miniaturization and complication of semiconductor devices, the cause of defect generation has become diverse and compositive in the process of manufacturing the devices. Accordingly, failure analysis technology has become increasingly important. In addition, an increase in the number of defects has led to a growing demand for defect review aimed at not only speeding up inspections but also extracting fatal defects.

Failure analysis is initiated by first detecting defect positions on a semiconductor wafer with an optical or electronic visual inspection apparatus. Defects detected by the visual inspection apparatus usually contain a large amount of noise, and insignificant defects as well. Accordingly, high-resolution images of the defect positions obtained using the visual inspection apparatus are taken using a defect review apparatus to perform defect classification by using the images thus obtained. Such defect classification work enables a discrimination to be made as to which is a critical defect to be failure-analyzed. In recent years, defect review apparatuses have come to be provided with a function of automatically classifying taken images of defects by using teaching data. This function is referred to as ADC (Automatic Defect Classification).

In failure analysis, there is used, for example, elemental analysis based on energy dispersive X-ray spectrometry (EDS) or electron energy-loss spectroscopy (EELS), in addition to high-resolution observation based on scanning electron microscopy (SEM) or transmission electron microscopy (TEM). In order to conduct a failure analysis based on transmission electron microscopy, a silicon wafer used in semiconductor manufacturing has to be cleaved into chips or columnar samples due to constraints on sample size. Thus, a laser or focused ion beam (FIB) apparatus is used in this processing.

At the time of sample preparation by such wafer cleaving or by the use of focused ion beams as described above, a mark of some sort is needed in order to isolate a defect of interest. That is, a mark of such size as can be visually recognized by a person is necessary in the case of wafer cleaving. On the other hand, a mark of such size as can be recognized on an SIM (Scanning Ion Microscopy) image displayed on the FIB apparatus is necessary at the time of sample preparation by the use of focused ion beams.

As one example of technologies to put such marks, JP 2000-241319A discloses an FIB apparatus equipped with an optical defect detection unit. In the apparatus, a mark is put in the vicinity of a defect position optically detected with a focused ion beam. Then, a focused ion beam is emitted to a sample on the basis of the mark to make a TEM sample. In addition. JP 2002-350731A shows an example of marking by means of indentation using diamond in an optical inspection/observation apparatus.

If an indentation mark is put in the vicinity of a defect under constant conditions regardless of the film type of samples, the surroundings of the mark become cracked, thus causing the problem of difficulty in viewing the mark or the defect. Alternatively, the mark may be too small to view, thus posing a problem for analysis using a subsequent-stage analyzer. In addition, if an indentation mark is put on a film not suited for marking in a patterned wafer, the mark may be difficult to view or foreign matter or dust may arise from the marked locations of the wafer.

The present invention is intended to provide a method for performing indentation marking appropriately, irrespective of the material and film type of a sample.

### SUMMARY OF THE INVENTION

In the present invention, marking suited for a film type is performed by varying such indentation marking conditions as the pressing load, descending rate, and marking depth of an indenter of an indentation marking unit on the basis of elemental analysis results obtained with an elemental analysis unit, such as an EDS. To that end, materials, i.e., the elemental analysis results and conditions of marking by the indentation marking unit are previously correlated with each other. Then, information on the correlation is stored in an apparatus.

In addition if the film type of a location to be marked cannot be concluded to be a registered film type as the result of elemental analysis, marking under wrong conditions is prevented by switching to manual setting. It is also possible to avoid putting marks on a material if the material is not suited for marking.

According to the present invention, marks excellent in shape are available automatically. Consequently, analysis using a subsequent-stage analyzer progresses efficiently, thereby enabling early defect cause investigation and yield improvement.

It is also possible to prevent indentations from being stamped so strongly that the surroundings of the indentations are destroyed to become a source of foreign matter or dust.

Objects, configurations and advantages of the present invention other than those described above will be apparent from the following description of an embodiment.

### BRIEF DESCRIPTION OF THE DRAWINGS

FIG. 1 is a schematic view illustrating an overall configuration example of a defect detection system and a defect review apparatus.

FIG. 2A is a schematic view illustrating the inside of a sample chamber at the time of defect review.

FIG. 2B is a schematic view illustrating the inside of a sample chamber at the time of indentation marking.

FIG. 3 is a flowchart illustrating one example of the operation of the defect review apparatus according to the present invention.

FIG. 4A is a schematic view illustrating an example of a marking method.

FIG. 4B is a schematic view illustrating a first example of improper indentation marking.

FIG. 4C is a schematic view illustrating a second example of improper indentation marking.

FIG. 4D is a schematic view illustrating a third example of improper indentation marking.

FIG. 4E is a schematic view illustrating a first example of countermeasure against the third example of improper indentation marking.

FIG. 4F is a schematic view illustrating a second example of countermeasure against the third example of improper indentation marking.

FIG. 5A is a graphical view illustrating a first example of EDS analysis results.

FIG. 5B is a graphical view illustrating a second example of EDS analysis results.

FIG. 5C is a graphical view illustrating a third example of EDS analysis results.

FIG. 6A is a table showing an example of indentation marking conditions.

FIG. 6B is a table showing another example of indentation marking conditions.

FIG. 7 is a schematic view illustrating an example of a marking conditions setting screen.

FIG. 8A is a schematic view illustrating another example of the marking method.

FIG. 8B is a schematic view illustrating yet another example of the marking method.

### DETAILED DESCRIPTION OF THE PREFERRED EMBODIMENT

Hereinafter, an embodiment of the present invention will be described with reference to the accompanying drawings.

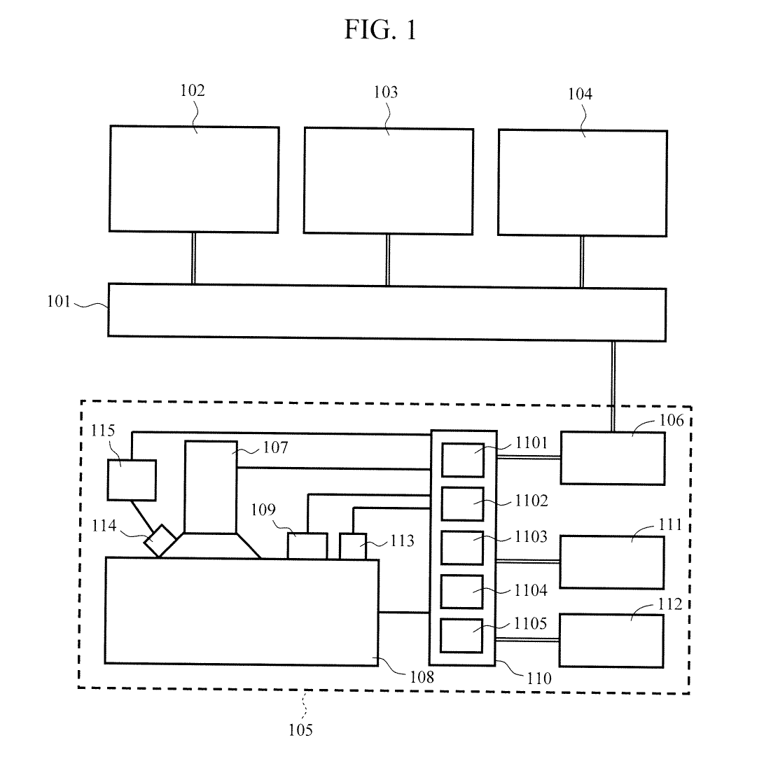

FIG. 1 illustrates an overall configuration example of a defect review apparatus according to the present invention and a configuration example of a defect detection system in which the defect review apparatus is arranged. A defect review apparatus 105 includes a scanning electron microscope column (electron optical column) 107; a sample chamber 108; an indentation marking unit 109; an optical microscope 113; a control section 110; an ADR (Automatic Defect Review) section 111; an ADC (automatic defect classification) section 112; and a communication computer 106, and is connected to a YMS (Yield Management System) 101 through a network. The YMS 101 is also connected to a bright-field optical visual inspection apparatus 102, a dark-field optical visual inspection apparatus 103, and an electron-beam visual inspection apparatus 104 through a network.

Inspection data is sent from these inspection apparatuses to the YMS 101, and further to the defect review apparatus 105, after the completion of inspection. The defect review apparatus 105 performs ADR and ADC by using this inspection data and returns ADR and ADC results to the YMS 101 through the communication computer 106.

Next, details on the defect review apparatus will be described. The scanning electron microscope column 107 has the function of emitting a primary electron beam to the object being inspected housed in the sample chamber to detect secondary electrons or reflection electrons thus obtained, and outputting a detection signal. An unillustrated sample stage is housed in the sample chamber 108. The sample stage moves a target position of irradiation with a primary electron beam or a target position of indentation by the indentation marking unit 109 on the object being inspected to below the scanning electron microscope column 107 or the indentation marking unit 109, according to a control signal from the control section 110. A scanning electron microscope image obtained by the scanning electron microscope column 107 is used to identify defect positions and set marking positions.

The optical microscope 113 is located on an upper portion of the sample chamber 108 and can take an optical microscope image of a defect. The scrolling of the optical microscope 113 is performed by the sample stage as in the case of the scanning electron microscope column 107. An optical microscope image thus obtained is used to locate defects not visible with a scanning electron microscope, and to set marking positions. An EDS detection section 114 can conduct an elemental analysis based on energy dispersive X-ray spectrometry through an EDS processing section 115. Results of the analysis can be used as material information.

The respective components of a scanning electron microscope associated with the defect review apparatus are controlled by the control section 110. The ADR section 111, the ADC section 112, and the communication computer 106 are connected to a subsequent stage of the scanning electron microscope. The ADR section 111 controls the control sequence of automatic defect review, and the ADC section 112 performs the automatic classification processing of defect images obtained by ADR. The control section 110 is equipped with various control units, including an electron optical column control unit 1101, an indentation marking unit control unit 1102, an optical microscope control unit 1103, a marking object defect extraction unit 1104 and a stage control unit 1105, in order to control the operation of the respective components of the scanning electron microscope. The communication computer 106 also serves as a management console of the defect review apparatus, and is equipped with a monitor on which a GUI (Graphical User's Interface) used to set operating conditions for defect review or an inspection recipe is displayed.

The respective control units described above are materialized by means of either software implementation or hardware implementation within the control section 110. Accordingly, the control section 110 is equipped therein a memory in which programs for realizing the functions of each control unit are stored and a processor for executing the programs. Alternatively, the control section 110 is equipped with a plurality of microcomputers corresponding to the functions of the individual control units.

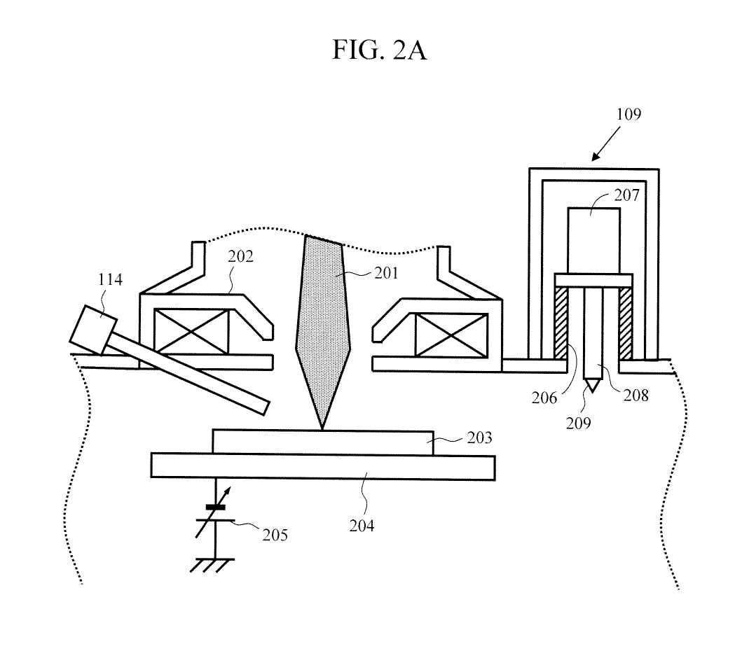

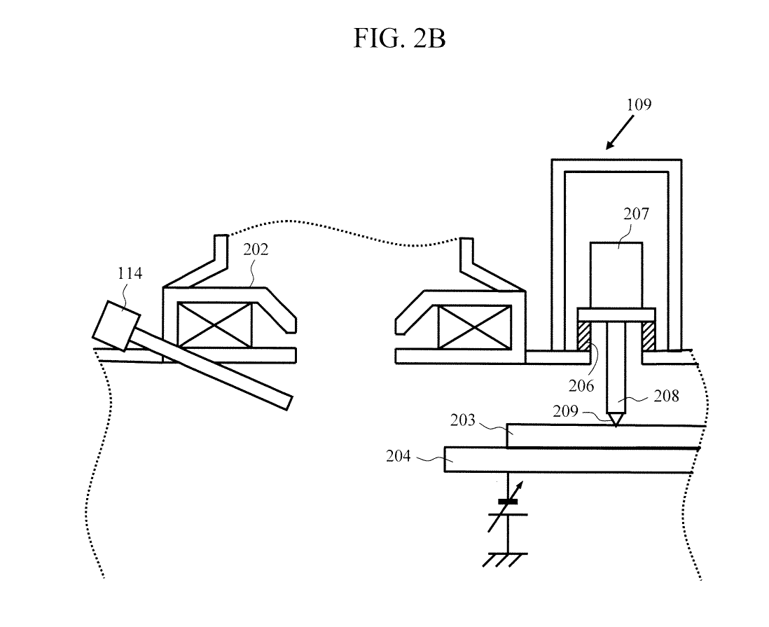

Next, details on the indentation marking unit of the present embodiment will be described using FIGS. 2A and 2B. FIG. 2A is a schematic view illustrating the inside of the sample chamber at the time of defect review. In the sample chamber 108, an electron beam 201 is focused by an objective lens 202 and emitted to a wafer 203 serving as a sample. The wafer 203 is mounted on a stage 204 and moved to an arbitrary position by the stage control unit 1105. The primary electron beam may be decelerated immediately before the sample 203, depending on the conditions of acquiring a scanning electron microscope image, to take an image of the sample 203. In that case, a retarding voltage is applied to the sample 203 by a retarding unit 205.

At the time of review, the stage 204 moves successively from one defect position to another, and an electron beam 201 focused by the objective lens 202 is emitted to respective defect positions to take SEM images thereof. Using these SEM images, defects are detected by the defect detection unit 111 and classified by a defect classification section. In addition to the original SEM images, results of defect detection and defect classification are uploaded to the YMS 101 through a network by using the communication computer 106.

FIG. 2B illustrates the inside of the sample chamber at the time of indentation marking. At the time of indentation marking, the stage control unit 1105 controls the stage 204 by using the position of each defect to be marked determined by the marking object defect extraction unit 1104 to move a target position of marking on the wafer 203 to below the indentation marking unit 109.

When movement is completed, the indentation marking unit 109 lowers and presses an indenter 209 attached to the leading end of a shaft 208 against the wafer 203 by a vertical drive mechanism 207 including a vacuum bellows 206, thereby forming an indentation mark on the sample. These actions of the indentation marking unit are controlled by the indentation marking unit control unit 1102.

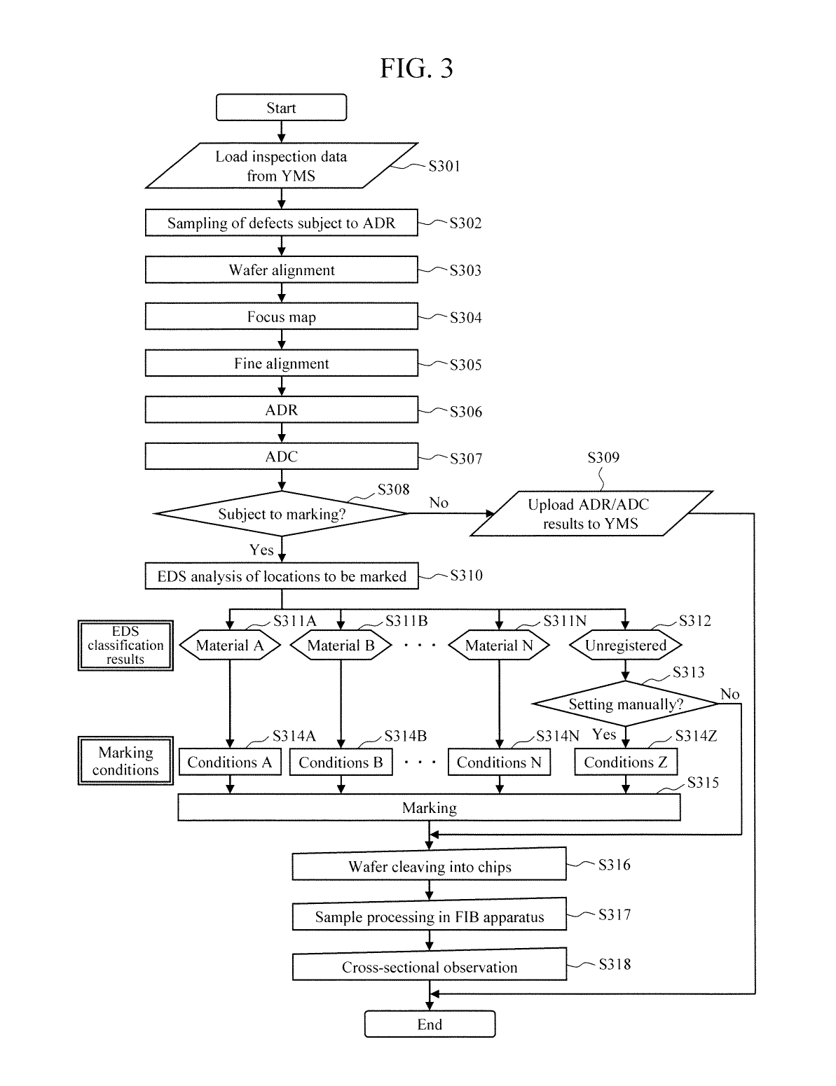

Next, the operation of the defect review apparatus of the present embodiment will be described using FIG. 3.

First, inspection data is read from the YMS in step 301. In step 302, sampling is performed to extract defects subject to ADR from defects included in the inspection data. The purpose of sampling is to narrow down target defects, so as to be able to conduct an effective ADR in a limited time in cases where defects are large in number. For this purpose, there are used such methods as extraction and removal of cluster defects and random extraction from defects other than the cluster defects. In step 303, wafer alignment is performed to coarsely align the wafer. In step 304, a focus map is plotted to correct a distribution of focuses for each region within a wafer plane, so that the wafer comes into an automatic focus in a short period of time. In step 305, the fine alignment of the scanning electron microscope is performed. The fine alignment is performed using unique patterns for respective mask shots in a photoprocess in the case of a patterned wafer. In the case of an unpatterned wafer, the fine alignment is performed by illuminating defects with an optical microscope, a dark-field microscope using a laser-light or the like in particular, to precisely detect defect positions. In step 306, the precise position of each defect is detected by ADR to obtain an SEM image centered around the defect. In step 307, a decision is made on classification results by ADC on the basis of the SEM image.

After ADC in step 307, the classification results are transferred from the ADC section 112 to the marking object defect extraction unit 1104 within the control section 110. The marking object defect extraction unit 1104 determines whether or not the classified defects are those to be marked, thereby extracting defects subject to marking (step 308). If any defects to be marked are not included in the classification results. ADR/ADC results are uploaded to the YMS 101 through the communication computer 106 to finish the operation (step 309).

If a defect is determined as one to be marked in step 308, an EDS analysis is made of a location to be marked (step 310). A determination is made from results of the EDS analysis as to whether or not the material of the location to be marked agrees with a pre-registered material. Materials may be registered as information generated by combining the peak positions of X-ray spectrums (energy or wavelengths) corresponding to the material with peak intensity (number of counts), or under specific material names.

(1) Material A (step 311A)
(2) Material B (step 311B)
. . .
(N) Material N (step 311N)

In this way, a determination is made as to which of the pre-registered materials A to N the material of the location to be marked corresponds to.

If the material is item (1), pre-registered conditions A are determined as marking conditions (step 314A).
If the material is item (2), pre-registered conditions B are determined as marking conditions (step 314B).
. . .
If the material is item (N), pre-registered conditions N are determined as marking conditions (step 314N).

If the material of the location to be marked does not agree with any of the pre-registered materials and is determined as being not registered (step 312), a query is made as to whether conditions for the material are set manually (step 313). If a decision is made in step 313 to manually set the conditions, a later-described manual setting screen appears to prompt inputting marking conditions. In this case, conditions Z thus input are determined as the marking conditions (step 314Z).

Once the marking conditions are determined, the indentation marking unit control unit 1102 controls the indentation marking unit 109 to actually perform marking under the marking conditions thus decided.

If a decision is made in step 313 not to manually set the conditions, marking is skipped.

In this process. EDS is used in elemental analysis, but the elemental analysis is not limited to this method. Alternatively, another elemental analysis method, such as WDS (Wavelength Dispersive X-ray Spectrometry) or AES (Auger Electron Spectrometry), may be used.

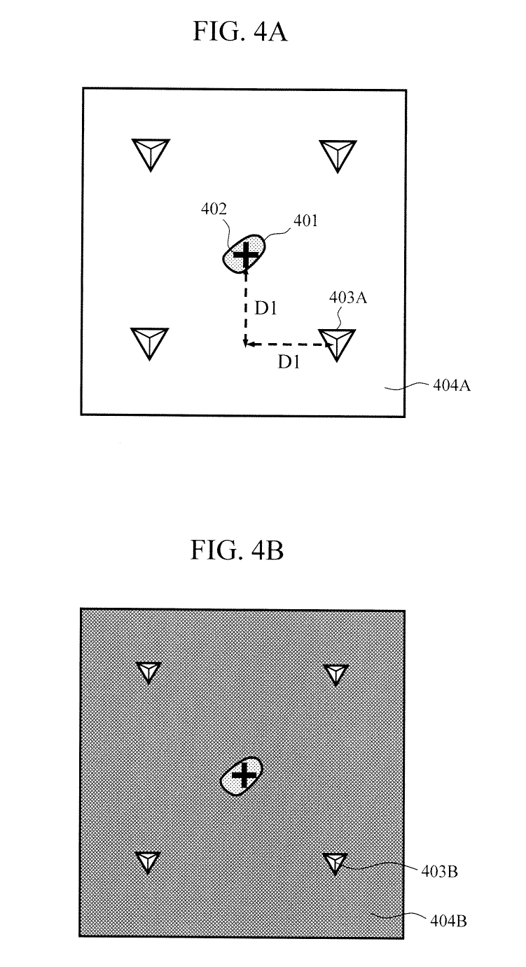

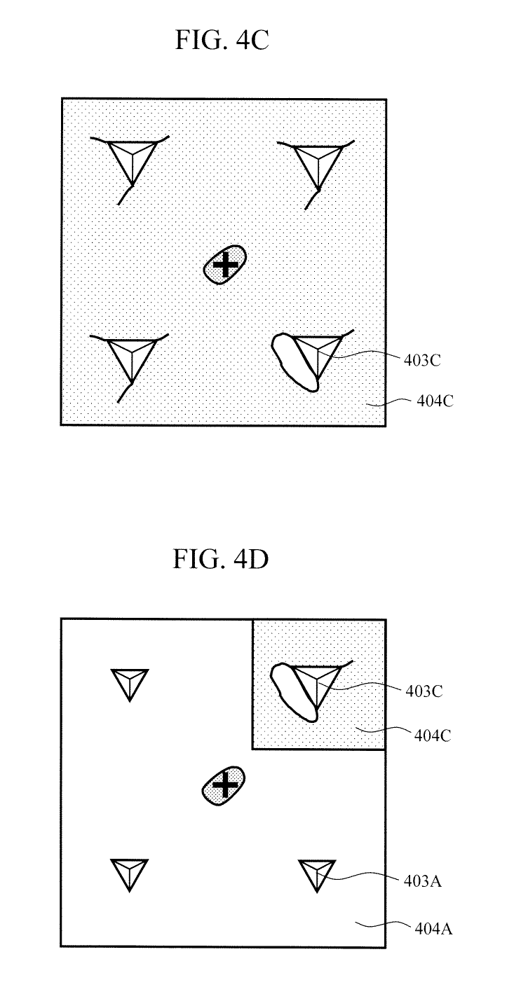

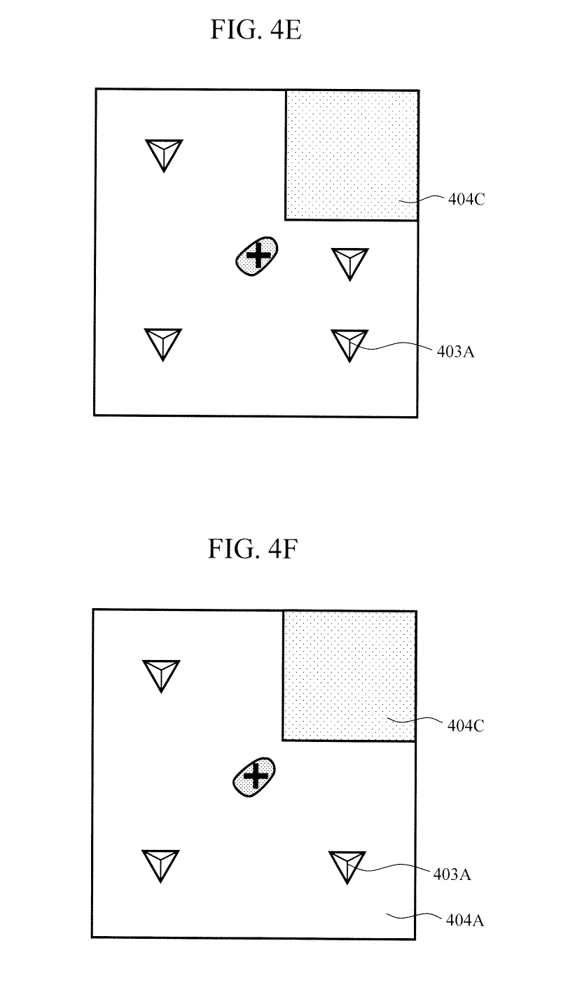

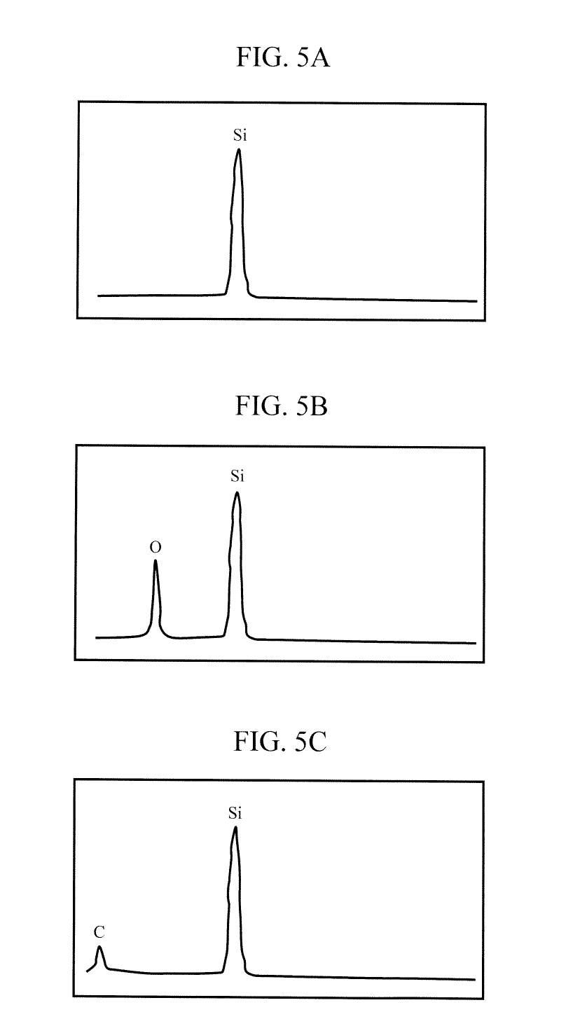

Next, a method for determining marking conditions in the present embodiment will be described using FIGS. 4A, 4B and 4C and FIGS. 5A, 5B and 5C. FIG. 4A is a schematic view illustrating marking positions in the present embodiment. A marking center 402 is set in substantially the middle of a defect 401, and a first indentation mark 403A is stamped in a position a distance of D1 away in an XY direction from the marking center. The distance D1 is determined in consideration of the coordinate accuracy of indentation marking and effects on the surroundings of the mark.

FIGS. 5A, 5B and 5C illustrate examples of EDS analysis results (spectrums). The axis of abscissas of FIGS. 5A, 5B and 5C represents energy and the axis of ordinates represents X-ray intensity (number of counts). FIGS. 5A, 5B and 5C correspond respectively to FIGS. 4A, 4B and 4C. FIG. 5A shows an example in which a spectrum is composed only of silicon of a substrate, FIG. 5B shows an example in which a silicon oxide film is deposited on silicon, and FIG. 5C shows an example in which a carbon-based film, such as a resist film, is attached to silicon.

FIG. 4A shows marks stamped on a silicon substrate 404A under correct marking conditions and formed so as to be free from cracks and the like, relatively large in size, and easy to view. If the pressing load or marking depth is inadequate for reasons of, for example, the material being too hard as in the case of a silicon oxide film 404B, a mark 403B is small, and therefore, difficult to view, as illustrated in FIG. 4B. In addition, if the pressing load of marking is too heavy for reasons of, for example, the material being too brittle as in the case of a resist film 404C, a mark 403C is large but may be cracked, or broken to come off, thus causing the defect to be difficult to view or to become a source of dust, as illustrated in FIG. 4C.

In the case of a patterned wafer, one or two of four marks may be coincidentally located on another film, as illustrated in FIG. 4D. In this case, an EDS analysis may be conducted for each marking position, so as to be able to vary marking conditions accordingly.

If a position on another film made of a different material coincides with a position to be marked, as illustrated in FIG. 4D, a mark may be stamped below that position, for example, as illustrated in FIG. 4E, while avoiding the position different in material, thereby changing the marking position. Alternatively, only the position different in material may be excluded from mark stamping, as illustrated in FIG. 4F.

If a patterned wafer is used and the pattern is too small, it is advantageous to use AES higher in spatial resolution than EDS at the time of elemental analysis.

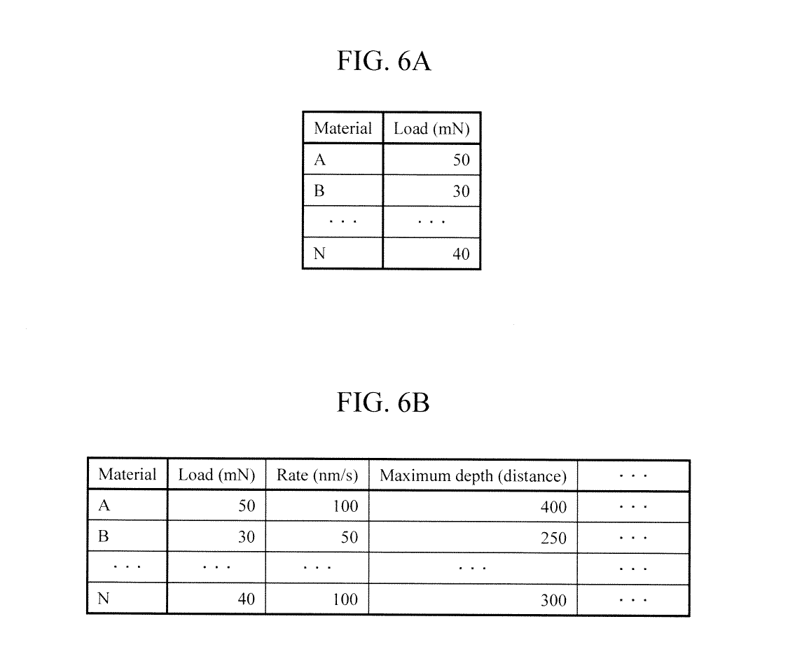

FIGS. 6A and 6B show examples of indentation marking conditions. FIG. 6A shows an example of setting the pressing load of the indenter as a marking condition according to the type of material. FIG. 6B shows an example of setting the pressing load, descending rate, maximum marking depth (distance) of the indenter as marking conditions on a material-by-material basis. As a matter of course, marking conditions are not limited to these examples. The indentation marking unit control unit 1102 stores, as information, such conditions as shown in this table. Marking conditions corresponding to the material in question are read out according to elemental analysis results. The indentation marking unit 109 is driven and controlled in accordance with the conditions thus read out to perform marking.

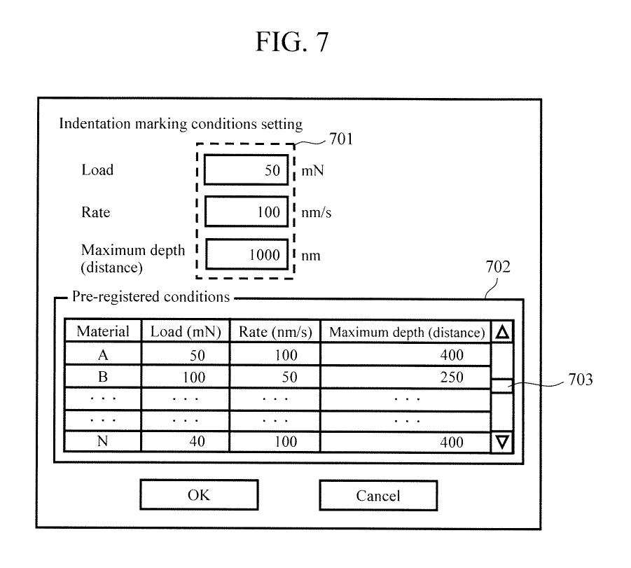

FIG. 7 illustrates an example of a marking conditions setting screen. This setting screen is displayed when Yes is selected for the query “Setting manually?” in step 313 of FIG. 3. An operator numerically inputs parameters denoted by reference numeral 701 on the screen. At that time, the operator can input parameters, while scrolling through pre-registered conditions 702 up and down with a scroll bar 703 for reference.

Referring back to FIG. 3, marking is finished after being performed on all of defects to be marked, and the sample 203 is moved out of the defect review apparatus.

The above-described process of indentation marking may be carried out manually by an equipment operator or may be executed automatically by the apparatus.

After the sample 203 is moved out, a decision is made on analysis objects. Examples of methods for selecting analysis objects include selecting main defects high in occurrence ratio among all defects, selecting rare defects unique to the wafer in question, and selecting several defects each from various types of defects to roughly observe the overall state thereof.

In addition, the wafer is cleaved into chips so as to fit into an holder of the analysis apparatus (step 316). In step 317, each chip is housed in the FIB apparatus to search out defect positions therein, and the front surface of each chip is protected, as necessary, by means of deposition or the like. Thereafter, a cross section of the chip desired to be observed is FIB-processed and the chip is thin-filmed to be taken out as a sample. In step 318, a cross-sectional observation is made of the thin sample thus obtained, using a TEM, a high-resolution SEM or the like.

In a conventional method, a sample is often loaded into an FIB apparatus without being provided with defect searching marks even for defects to be failure-analyzed. Thus, time is taken in the step of searching for defects in the FIB apparatus. In the case of an unpatterned bare wafer, a film-formed wafer or the like in particular, time is taken in searching for minute defects. According to the present embodiment, indentation marks can be directly attached to a significant defect in the defect review apparatus. Consequently, search for processing positions on the analyzer side becomes more efficient than before.

As has been described heretofore, the present embodiment allows significant defects to be selected as analysis objects in a subsequent stage in accordance with a predetermined strategy, thereby enabling early defect cause investigation and yield improvement. In addition, defects unobservable with an SEM can also be analyzed to enable yield improvement.

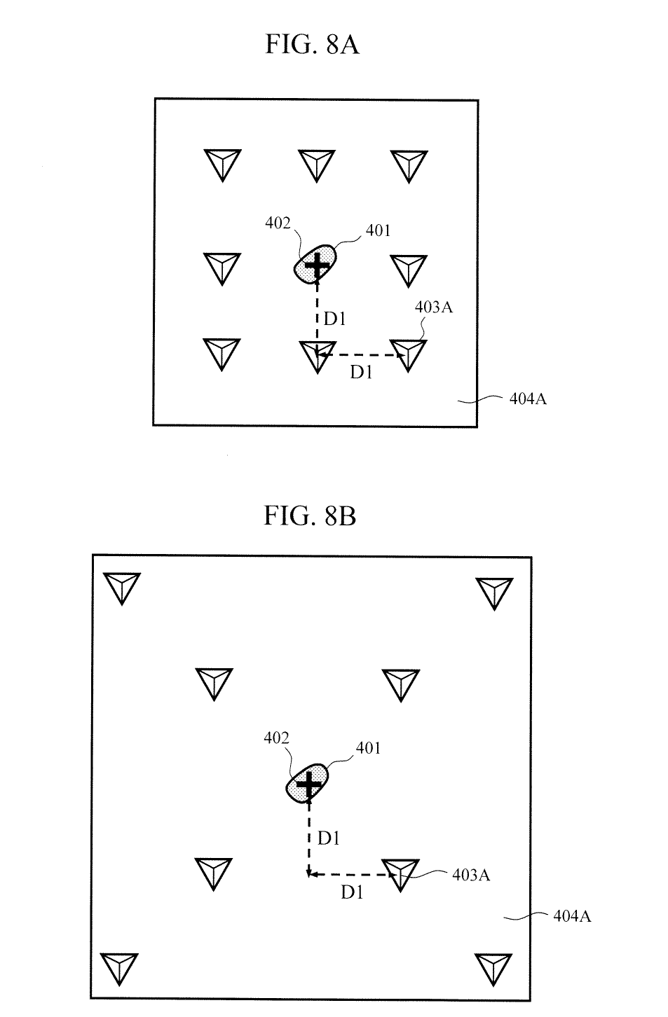

Yet additionally, although the way indentations are stamped has been described by citing a method for squarely stamping four marks around each defect, methods of marking are not limited to this method. As illustrated by way example in FIGS. 8A and 8B, the number of indentations may be increased to improve visibility.

It should be noted that the present invention is not limited to the foregoing embodiment but encompasses various modified examples. For example, the foregoing embodiment has been described in detail for the purpose of easier understanding of the present invention and is, therefore, not necessarily limited to apparatuses including all of the configurations mentioned above.

### DESCRIPTION OF SYMBOLS

101 YMS
102 Bright-field optical visual inspection apparatus
103 Dark-field optical visual inspection apparatus
104 Electron-beam visual inspection apparatus
105 Defect review apparatus
106 Communication computer
107 Scanning electron microscope column
108 Sample chamber
109 Indentation marking unit
110 Control section
111 ADR section
112 ADC section
113 Optical microscope
114 EDS detector
115 EDS processing section
201 Electron beam
202 Objective lens
203 Sample (wafer)
204 Stage
205 Retarding unit
206 Vacuum bellows
207 Vertical drive mechanism
208 Shaft
209 Indenter
401 Defect
402 Center position of defect
403A, 403B, 403C Indentation marking
1101 Electron optical column control unit
1102 Indentation marking unit control unit
1103 Optical microscope control unit
1104 Marking object defect extraction unit
1105 Stage control unit

What is claimed is:

1. A sample observation apparatus having a function of obtaining a scanning electron microscope image of a known defect position on a sample to observe the defect position, the apparatus comprising:
a sample stage operable to move with the sample mounted thereon;
an electron optical column for emitting a primary electron beam to the known defect position of the sample and outputting a secondary electron beam or a reflection electron beam thus obtained as a detection signal;
an elemental analysis unit for analyzing elements in the surroundings of the defect position of the sample;
an indentation marking unit equipped with an indenter to attach marks to a plurality of positions around the defect position of the sample by means of indentation with the indenter; and
a control section for controlling the indentation marking unit,
wherein the control section stores information obtained by correlating elemental analysis results provided by the elemental analysis unit with marking conditions to be used by the indentation marking unit.

2. The sample observation apparatus according to claim 1, wherein the marking conditions are determined by referring to the information on the basis of the elemental analysis results with respect to the surroundings of the defect position.

3. The sample observation apparatus according to claim 2, wherein the marking conditions include the pressing load of the indenter.

4. The sample observation apparatus according to claim 1, wherein the positions to be marked are changed on the basis of the elemental analysis results with respect to the surroundings of the defect position.

5. The sample observation apparatus according to claim 1, wherein the attachment of marks is stopped if the elemental analysis results with respect to the surroundings of the defect position do not correspond to any of pre-registered materials.

6. The sample observation apparatus according to claim 1, wherein if the elemental analysis results with respect to the surroundings of the defect position do not correspond to any of pre-registered materials, the apparatus switches to a mode for manually setting the marking conditions.

7. A marking method comprising the steps of:
obtaining a scanning electron microscope image of a known defect position on a sample to observe the defect position;
selecting a defect position subject to marking;
analyzing elements in the surroundings of the selected defect position;
referring to information obtained by correlating the results of the elemental analysis with marking conditions to be used by an indentation marking unit to determine marking conditions; and
attaching indentation marks to a plurality of positions around the defect position by the indentation marking unit in accordance with the determined marking conditions.

8. The marking method according to claim 7, wherein the marking conditions include the pressing load of an indenter of the indentation marking unit.
